(19) United States
(12) Patent Application Publication
(10) Pub. No.: US 2025/0379094 A1
(43) Pub. Date: Dec. 11, 2025

(54) CONVEYANCE APPARATUS, CONVEYANCE METHOD, AND METHOD FOR MANUFACTURING SEMICONDUCTOR DEVICE

(71) Applicant: JSW AKTINA SYSTEM CO., LTD., Yokohama-shi, Kanagawa (JP)

(72) Inventors: Ryo SHIMIZU, Yokohama-shi, Kanagawa (JP); Takahiro FUJI, Yokohama-shi, Kanagawa (JP); Yoshihiro YAMAGUCHI, Yokohama-shi, Kanagawa (JP); Tamotsu ODAJIMA, Yokohama-shi, Kanagawa (JP)

(73) Assignee: JSW AKTINA SYSTEM CO., LTD., Yokohama-shi, Kanagawa (JP)

(21) Appl. No.: 18/878,266

(22) PCT Filed: Jul. 7, 2022
(86) PCT No.: PCT/JP2022/027014

§ 371 Date: Dec. 23, 2024

(51) Int. Cl. H01L 21/687

(52) U.S. Cl. CPC H01L 21/687

(57) ABSTRACT

A conveyance apparatus (600) according to an embodiment is configured to convey a substrate (100) in order to irradiate the substrate (100) with line-shaped laser light (15), and includes: a main levitation unit (10) including an irradiation area disposed directly below an irradiation place of the laser light, and configured to levitate the substrate over a top surface thereof; a holding mechanism (11) disposed outside the main levitation unit (10) and configured to hold the substrate (100) over the main levitation unit; a first moving mechanism configured to move the holding mechanism (11) in a first direction in order to change the irradiation place of the laser light over the substrate (100); and a second moving mechanism configured to move the holding mechanism and the first moving mechanism in a second direction inclined from the first direction.

### TECHNICAL FIELD

The present invention relates to a conveyance apparatus, a conveyance method, and a method for manufacturing a semiconductor device.

### BACKGROUND ART

Patent Literature 1 discloses a laser annealing apparatus for forming a polycrystalline silicon thin film. In Patent Literature 1, a projection lens concentrates laser light over a substrate so that the laser light forms a linear irradiation area. As a result, an amorphous silicon film is crystallized and becomes a polysilicon film.

In Patent Literature 1, a conveyance unit conveys the substrate while a levitation unit levitates the substrate. Further, the substrate is carried into the levitation unit and carried out therefrom at the same place in the levitation unit. The conveyance unit conveys the substrate along each of the sides of the levitation unit. Further, the substrate is conveyed in a circulating manner twice over the levitation unit, so that substantially the entire surface of the substrate is irradiated with laser light.

### CITATION LIST

### Patent Literature

Patent Literature 1: Japanese Unexamined Patent Application Publication No. 2018-64048

### SUMMARY OF INVENTION

In such a conveyance apparatus for a laser irradiation apparatus, it is desired to appropriately convey a substrate so that a laser irradiation process is performed at a high speed and in a stable manner.

Other problems to be solved and novel features will become apparent from descriptions in this specification and accompanying drawings.

According to an embodiment, a conveyance apparatus is configured to convey a substrate in order to irradiate the substrate with line-shaped laser light, and includes: a main levitation unit including an irradiation area disposed directly below an irradiation place of the laser light, and configured to levitate the substrate over a top surface thereof; a holding mechanism disposed outside the main levitation unit, and configured to hold the substrate over the main levitation unit; a first moving mechanism configured to move the holding mechanism in a first direction in order to change the irradiation place of the laser light over the substrate; and a second moving mechanism configured to move the holding mechanism and the first moving mechanism in a second direction inclined from the first direction in order to change the irradiation place of the laser light over the substrate.

According to an embodiment, a conveyance apparatus is configured to convey a substrate in order to irradiate the substrate with line-shaped laser light, and includes: a main levitation unit including an irradiation area disposed directly below an irradiation place of the laser light, and configured to levitate the substrate over a top surface thereof; a levitation unit disposed outside the main levitation unit, including an opening provided along a first direction, and configured to eject gas onto a bottom surface of the substrate; a holding mechanism disposed in the opening and configured to hold the substrate; and a first moving mechanism configured to move the holding mechanism and the levitation unit along the first direction.

According to an embodiment, a conveyance method is a conveyance method for conveying a substrate by using a conveyance apparatus in order to irradiate the substrate with line-shaped laser light, the conveyance apparatus including: a main levitation unit including an irradiation area disposed directly below an irradiation place of the laser light, and configured to levitate the substrate over a top surface thereof; and a holding mechanism disposed outside the main levitation unit, and configured to hold the substrate over the main levitation unit, the conveyance method including the steps of: (A1) moving, by a first moving mechanism, the holding mechanism in a first direction in order to change the irradiation place of the laser light over the substrate; and (A2) moving, by a second moving mechanism, the holding mechanism and the first moving mechanism in a second direction inclined from the first direction in order to change the irradiation place of the laser light over the substrate.

According to an embodiment, in a conveyance method using a conveyance apparatus configured to convey a substrate in order to irradiate the substrate with line-shaped laser light, and the conveyance apparatus includes: a main levitation unit including an irradiation area disposed directly below an irradiation place of the laser light, and configured to levitate the substrate over a top surface thereof; a movable levitation unit disposed outside the main levitation unit, including an opening provided along a first direction, and configured to eject gas onto a bottom surface of the substrate; and a holding mechanism disposed in the opening and configured to hold the substrate, and the conveyance method includes the step of (B1) moving, by a first moving mechanism, the holding mechanism and the movable levitation unit along the first direction.

According to an embodiment, a method for manufacturing a semiconductor device includes the steps of: (sa1) forming an amorphous film over a substrate; (sa2) loading the substrate with the amorphous film formed thereover onto a conveyance apparatus; and (sa3) irradiating the substrate with line-shaped laser light while conveying the substrate using the conveyance apparatus, and thereby annealing the amorphous film so that the amorphous film is crystallized into a crystallized film, the conveyance apparatus including: a main levitation unit including an irradiation area disposed directly below an irradiation place of the laser light, and configured to levitate the substrate over a top surface thereof; a holding mechanism disposed outside the main levitation unit, and configured to hold the substrate over the main levitation unit; a first moving mechanism configured to move the holding mechanism in a first direction in order to change the irradiation place of the laser light over the substrate; and a second moving mechanism configured to move the holding mechanism and a first moving mechanism configured to move the holding mechanism and the levitation unit along the first direction.

According to an embodiment, a method for manufacturing a semiconductor device includes the steps of: (sb1) forming an amorphous film over a substrate; (sb2) loading the substrate with the amorphous film formed thereover onto a conveyance apparatus; and (sb3) irradiating the substrate with line-shaped laser light while conveying the substrate using the conveyance apparatus, and thereby annealing the amorphous film so that the amorphous film is crystallized into a crystallized film, in which the conveyance apparatus includes: a main levitation unit including an irradiation area disposed directly below an irradiation place of the laser light, and configured to levitate the substrate over a top surface thereof; a levitation unit disposed outside the main levitation unit, including an opening provided along a first direction, and configured to eject gas onto a bottom surface of the substrate; and a holding mechanism disposed in the opening and configured to hold the substrate, and the method includes the step of moving, by a first moving mechanism, the holding mechanism and the levitation unit along the first direction.

According to the above-described embodiments, it is possible to perform conveyance of a substrate suitable for a laser irradiation process.

### BRIEF DESCRIPTION OF DRAWINGS

FIG. 1 is a plan view schematically showing a configuration of a conveyance apparatus used in a laser irradiation apparatus;

FIG. 2 is a side cross-sectional view schematically showing a laser irradiation apparatus;

FIG. 3 is a side cross-sectional view schematically showing a laser irradiation apparatus;

FIG. 4 is a plan view for explaining a configuration before a substrate is irradiated with laser light;

FIG. 5 is a plan view for explaining a configuration during irradiation by laser light;

FIG. 6 is a plan view for explaining a conveyance direction and an inclination of a substrate;

FIG. 7 is a plan view for explaining a conveyance step in a conveyance apparatus;

FIG. 8 is a plan view for explaining a conveyance step in the conveyance apparatus;

FIG. 9 is a plan view for explaining a conveyance step in the conveyance apparatus;

FIG. 10 is a plan view for explaining a conveyance step in the conveyance apparatus;

FIG. 11 is a plan view for explaining a conveying process in the conveyance apparatus;

FIG. 12 is a plan view for explaining a conveying process in the conveyance apparatus;

FIG. 13 is a plan view for explaining a conveying process in the conveyance apparatus;

FIG. 14 is a plan view for explaining a conveying process in the conveyance apparatus;

FIG. 15 is a plan view for explaining a conveying process in the conveyance apparatus;

FIG. 16 is a cross-sectional view showing a simplified configuration of an organic EL display device;

FIG. 17 is a cross-sectional view showing a process in a method for manufacturing a semiconductor device according to an embodiment; and

FIG. 18 is a cross-sectional view showing a process in the method for manufacturing the semiconductor device according to the embodiment.

### DESCRIPTION OF EMBODIMENTS

A conveyance apparatus according to an embodiment is used in a laser irradiation apparatus such as a laser annealing apparatus. The laser annealing apparatus is, for example, an ELA (Excimer Laser Anneal) apparatus that forms an LTPS (Low Temperature Poly-Silicon) film. A conveyance apparatus, a laser irradiation apparatus, a method, and a manufacturing method according to this embodiment will be described hereinafter with reference to the drawings.

### First Embodiment

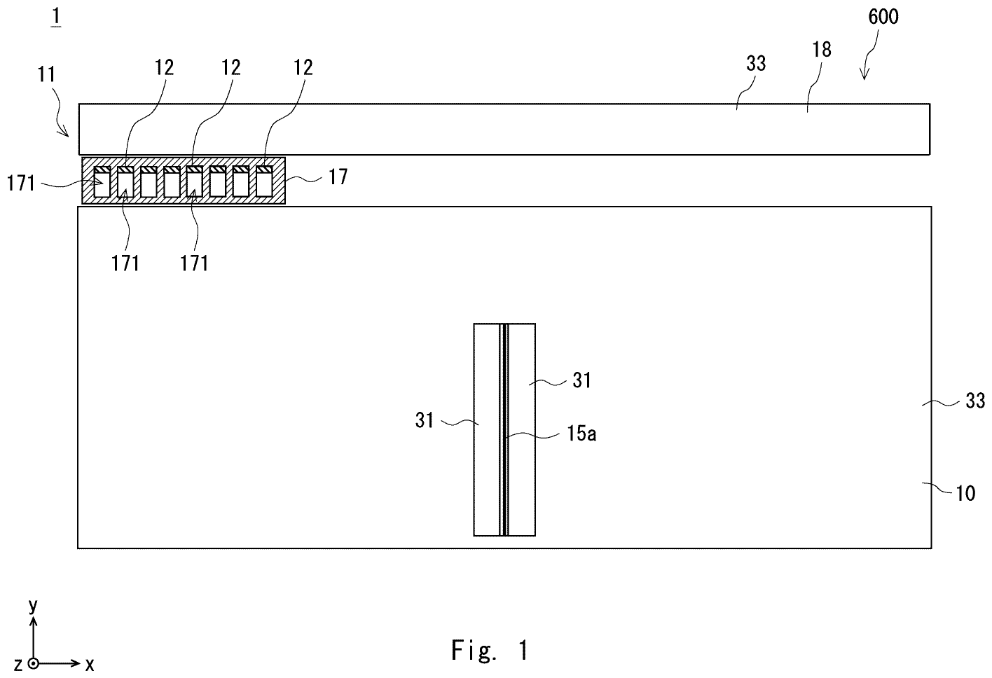

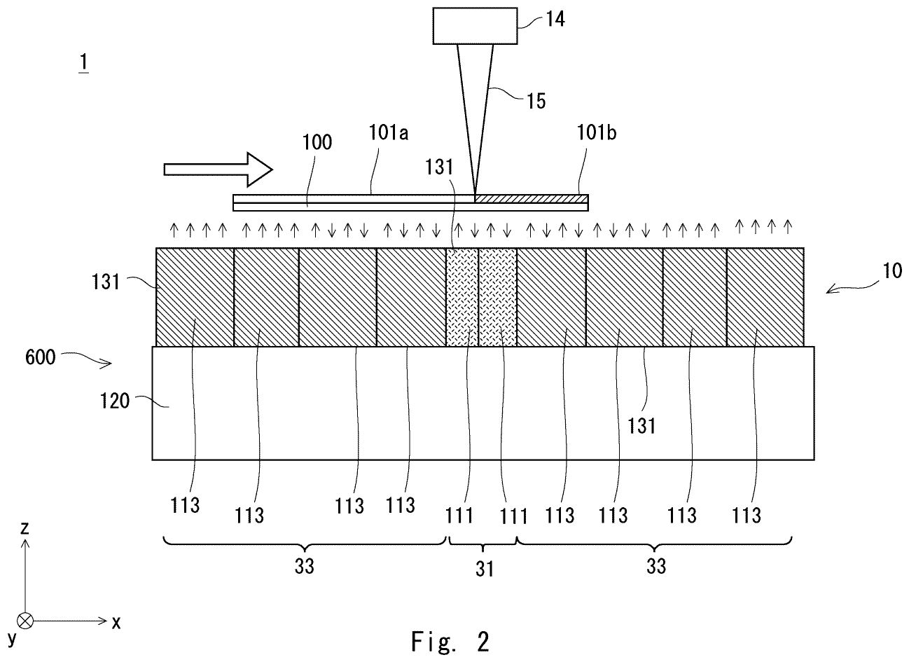

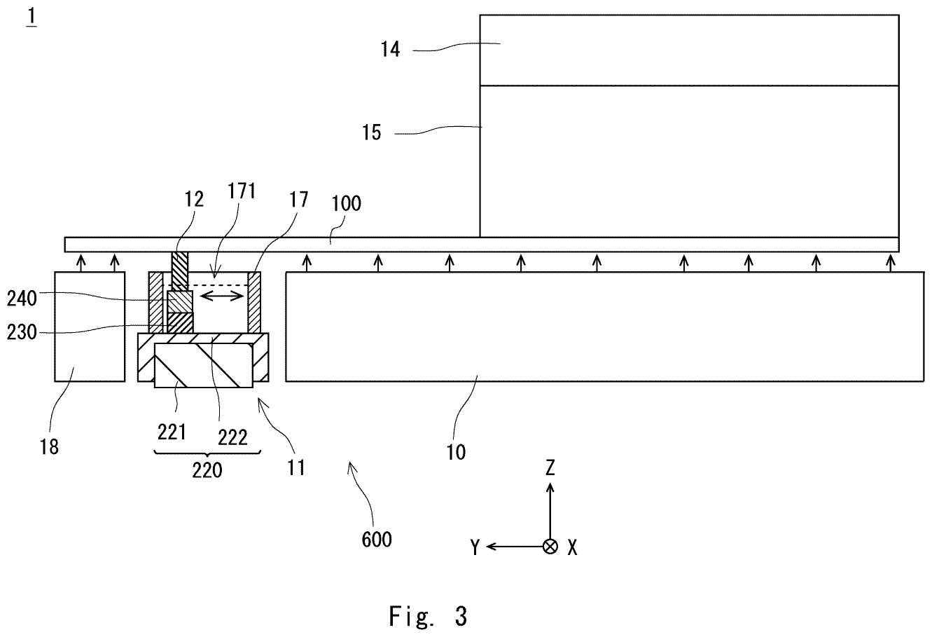

A fundamental configuration of a conveyance apparatus and a laser irradiation apparatus according to this embodiment will be described with reference to FIGS. 1 to 3. FIG. 1 is a plan view schematically showing a fundamental configuration of a conveyance apparatus 600. FIG. 2 is a side cross-sectional view schematically showing the configuration of the conveyance apparatus. FIG. 3 is a side cross-sectional view schematically showing the configuration of the conveyance apparatus.

Note that in the drawings described below, an xyz three-dimensional orthogonal coordinate system is shown as appropriate for the sake of simplifying the description. The z direction is a vertical direction, and the y direction is a line direction along a linear irradiation area 15a. The x direction is a direction perpendicular to the z and Y directions. That is, the y direction is the longitudinal direction (i.e., the long-side direction) of the linear irradiation area 15a, and the x direction is the lateral direction (i.e., the short-side direction) perpendicular to the longitudinal direction.

Note that FIGS. 1 to 3 are conceptual diagrams showing only the fundamental configuration of the conveyance apparatus and the laser irradiation apparatus, and parts of the configuration thereof are omitted. For example, in FIG. 1, the conveyance apparatus 600 is shown in a simplified manner. Specifically, in FIG. 1, a laser irradiation unit 14, a precision levitation unit 111, and a rough levitation unit 113 are omitted.

As shown in FIGS. 1 to 3, the laser irradiation apparatus 1 includes a main levitation unit 10, a conveyance unit 11, and a laser irradiation unit 14. The main levitation unit 10 and the conveyance unit 11 constitute the conveyance apparatus 600. Further, the conveyance apparatus 600 may include an end levitation unit 18.

As shown in FIG. 2, the main levitation unit 10 is configured so that gas is ejected from the surface of the main levitation unit 10. The substrate 100 is levitated by the main levitation unit 10 over the top surface thereof. The substrate 100 is levitated as the gas ejected from the surface of the main levitation unit 10 is blown onto the bottom surface of the substrate 100. The substrate 100 is, for example, a glass substrate. When the substrate 100 is conveyed, the main levitation unit 10 adjusts the levitation height of the substrate 100 so that it does not collide with any of other mechanisms (not shown) disposed above the substrate 100.

The main levitation unit 10 is principally divided into a precision levitation area 31 and a rough levitation area 33. The precision levitation area 31 is an area including the irradiation area 15a of the laser light 15. That is, in the xy-plan view, the precision levitation area 31 is an area that coincides with the focal point (irradiation area 15a) of the laser light. The precision levitation area 31 is an area larger than the irradiation area 15a.

The rough levitation area 33 is an area adjacent to the precision levitation area 31. The rough levitation area 33 is, i.e., two rough levitation areas 33 are, arranged on both sides of the precision levitation area 31 in the x direction. In the xy-plan view, the rough levitation area 33 is an area that does not overlap the focal point (irradiation area 15a) of the laser light.

Each of the precision levitation unit 111 and the rough levitation unit 113 ejects gas (e.g., air) upward. Further, the gas ejected from the precision levitation unit 111 and the rough levitation unit 113 may be an inert gas such as nitrogen. As the gas is blown onto the bottom surface of the substrate 100, the substrate 100 is levitated. As a result, the main levitation unit 10 and the substrate 100 are no longer contact with each other. Further, the precision levitation unit 111 sucks the gas present between the substrate 100 and the main levitation unit 10. The rough levitation unit 113 may be configured to suck gas in a manner similar to the precision levitation unit 111, or may not be configured to suck the gas.

For example, a gas supply source(s) (not shown) for supplying gas is connected to the precision levitation unit 111 and the rough levitation unit 113. Further, a vacuum generation source(s) (not shown) for sucking gas is connected to the precision levitation unit 111 and the rough levitation unit 113. The gas supply source is a compressor, a gas cylinder, or the like, and supplies compressed gas. The vacuum generation source is a vacuum pump, an ejector, or the like.

The accuracy of the levitation height by the precision levitation unit 111 is higher than that of the levitation height by the rough levitation unit 113. Further, the substrate 100 is irradiated with laser light in the precision levitation area 31 having the highest accuracy of the levitation height. Note that a semi-precision levitation unit may be provided between the precision levitation unit 111 and the rough levitation unit 113. The accuracy of the levitation height by the semi-precision levitation unit is lower than that of the precision levitation unit 111 and higher than that of the rough levitation unit 113.

For example, high accuracy is required for the levitation height of the substrate 100 in the irradiation area 15a and the precision levitation area 31 therearound. Therefore, the precision levitation unit 111 capable of controlling the levitation height with high accuracy is used. The precision levitation unit 111 is a precision levitation unit formed of a porous element such as ceramic.

Then, the precision levitation unit 111 ejects gas upward. Further, suction holes for sucking gas may be provided in the precision levitation unit 111. In the porous element, suction holes extending to its top surface are formed, e.g., machined, at predetermined intervals. The suction holes are minute holes and form a negative pressure between the substrate 100 and the precision levitation unit. Further, gas is ejected from almost the entire surface of the porous element except for the suction holes. The ejection surface that forms a positive pressure is formed over almost the entire surface except for the suction holes.

The rough levitation unit 113 is formed of a metal material. For example, the rough levitation unit 113 is formed of a metal block having a hollow part. Further, a plurality of ejection holes extending from the hollow part of the metal block to the top surface thereof are formed. Further, suction holes for sucking gas may be provided in the metal block. Note that the semi-precision levitation unit may be formed of a metal material as in the case of the rough levitation unit 113.

The rough levitation unit 113 and the precision levitation unit 111 are also collectively referred to as levitation unit cells 131. In the rough levitation area 33, a plurality of rough levitation units 113 are provided as levitation unit cells 131. In the precision levitation area 31, a plurality of precision levitation units 111 are provided as levitation unit cells 131. A semi-precision levitation area may be provided between the precision levitation area 31 and the rough levitation area 33.

The pedestal 120 is, for example, a metal plate. The precision levitation unit 111 and the rough levitation unit 113 are fixed to the pedestal 120 by, for example, bolts. The heights of the top surfaces of the precision levitation unit 111 and the rough levitation unit 113 are substantially equal to each other. That is, the top surface (levitation surface) of the main levitation unit 10 is substantially flat. The surface of the pedestal 120 may be polished so as to have a predetermined flatness. Further, an internal space (not shown) serving as a flow path for ejecting or sucking gas may be provided inside the pedestal 120. The levitation unit cells 131 may suck or eject gas through the internal space of the pedestal 120.

The end levitation unit 18 is provided on the +y side of the main levitation unit 10. The end levitation unit 18 is disposed directly below the end of the substrate 100. Similarly to the main levitation unit 10, the end levitation unit 18 ejects gas onto the bottom surface of the substrate 100. The end of the substrate 100 is levitated by the gas ejected from the top surface of the end levitation unit 18. The end levitation unit 18 has a configuration similar to that of the rough levitation unit. The end levitation unit 18 is formed of a metal material having ejection holes or the like.

The conveyance unit 11 conveys the levitated substrate 100 in the conveyance direction. The conveyance unit 11 is provided at the end of the main levitation unit 10 in the +y direction. Specifically, the conveyance unit 11 is disposed between the main levitation unit 10 and the end levitation unit 18 in the y direction. As shown in FIG. 3, the conveyance unit 11 includes holding mechanisms 12, a movable levitation unit 17, an x-moving mechanism 220, y-moving mechanisms 230, and lifting/lowering mechanisms 240.

The holding mechanisms 12 hold the substrate 100. For example, the holding mechanism 12, i.e., each holding mechanism 12, can be formed by using a vacuum suction mechanism. The vacuum suction mechanism is formed of a metal material, a resin-based material, a porous material, or the like. Absorption grooves, absorption holes, or the like are formed on the top surface of the holding mechanism 12. The holding mechanism 12 may be formed of a porous material.

The holding mechanism 12 (the vacuum suction mechanism) is connected to an exhaust port (not shown) and the exhaust port is connected to an ejector, a vacuum pump, or the like. Therefore, since a negative pressure for sucking gas acts, i.e., is formed, in the holding mechanisms 12, the substrate 100 can be held by using the holding mechanisms 12.

The holding mechanisms 12 hold the substrate 100 by sucking the surface (bottom surface) of the substrate 100 opposite to the surface (top surface) thereof which is irradiated with the laser light 15, i.e., the surface of the substrate 100 opposed to the main levitation unit 10. In FIG. 1, the holding mechanisms 12 hold the end of the substrate 100 in the +y direction.

As shown in FIG. 3, the holding mechanisms 12 are supported by lifting/lowering mechanisms 240 for performing a sucking operation. The lifting/lowering mechanisms 240 lift and lower the holding mechanisms 12. Each of the lifting/lowering mechanisms 240 includes, for example, an actuator such as an air cylinder or a motor. Each of the lifting/lowering mechanisms 240 further includes a linear guide mechanism along the Z direction. Therefore, the lifting/lowering mechanisms 240 can move the holding mechanisms 12 up and down. For example, the holding mechanisms 12 suck the substrate 100 in a state in which they are lifted to a sucking position. Further, the holding mechanism 12 is lowered to a standby position in a state where the sucking is cancelled, i.e., stopped.

A movable levitation unit 17 is disposed around each of the holding mechanisms 12. The movable levitation unit 17 ejects gas onto the substrate 100. The movable levitation unit 17 ejects gas onto the bottom surface of the substrate 100 in a manner similar to the main levitation unit 10. The end of the substrate 100 is levitated by the gas ejected from the top surface of the movable levitation unit 17. For example, the movable levitation unit 17 has a configuration similar to that of the rough levitation unit 113. The movable levitation unit 17 is made of a metal material having ejection holes or the like.

The movable levitation unit 17, i.e., each movable levitation unit 17, includes an opening 171 in which a holding mechanism 12 is disposed. The holding mechanisms 12 are disposed inside the openings 171 provided in the movable levitation units 17. As shown in FIG. 1, each of the openings 171 is provided, i.e., extends, along the y direction. Specifically, in the xy-plan view, each of the openings 171 is formed in a rectangular shape in which the y direction is the longitudinal direction, and the x direction is the lateral direction.

Further, a plurality of openings 171 are provided in the movable levitation unit 17. The plurality of openings 171 are arranged along the x direction. Note that although eight openings 171 are arranged along the x direction in FIG. 1, only one opening 171 may be provided or a plurality of openings 171 may be provided. A holding mechanism 12 is disposed in each of the openings 171. Each holding mechanism 12 sucks and holds the substrate 100.

The y-moving mechanisms 230 move the holding mechanisms 12 in the y direction. For example, the holding mechanisms 12 and the lifting/lowering mechanisms 240 are disposed over the y-moving mechanisms 230. That is, the y-moving mechanisms 230 movably support the holding mechanisms 12 and the lifting/lowering mechanisms 240. The y-moving mechanisms 230 includes an actuator such as a motor (not shown). The y-moving mechanisms 230 move the holding mechanisms 12 and the lifting/lowering mechanisms 240 in the y direction. As a result, the holding mechanisms 12 move the openings 171 in the y direction.

The x-moving mechanism 220 moves the holding mechanisms 12, the movable levitation unit 17, the lifting/lowering mechanisms 240, and the y-moving mechanisms 230 in the x direction. For example, the x-moving mechanism 220 includes a guide part 221 and a movable part 222. The guide part 221 serves as a stage for movably supporting the movable part 222. The guide part 221 is provided along the x direction. The x-moving mechanism 220 includes an actuator such as a motor (not shown). By the driving of the actuator, the movable part 222 moves over the guide part 221 in the x direction.

Further, the y-moving mechanisms 230 are provided over the movable part 222. That is, the movable part 222 supports the y-moving mechanisms 230 in such a manner that they are movable in the y direction. In the movable part 222, a guide mechanism such as a guide groove(s) or a guide rail(s) may be formed along the y direction.

The movable part 222 slides in the x direction over the guide part 221. Further, the y-moving mechanisms 230 slide in the y direction over the movable part 222. In this way, the holding mechanisms 12 move in the x and y directions. Therefore, the conveyance unit 11 can convey the substrate 100 in the x and y directions. By adjusting the moving speeds of the substrate 100 in the x and y directions, the conveyance direction of the substrate 100 can be changed. That is, by increasing the ratio of the moving speed in the y direction to that in the x direction, the angle formed by the x direction and the conveyance direction can be increased. By setting the moving speed in the y direction to zero, the conveyance direction becomes parallel to the x direction.

Further, the movable part 222 supports the movable levitation unit 17. Therefore, the movable part 222 moves the movable levitation unit 17 together with the y-moving mechanisms 230 in the x direction. Therefore, the movable levitation unit 17, the y-moving mechanisms 230, the lifting/lowering mechanisms 240, and the holding mechanisms 12 move together with the movable part 222. The movable part 222 serves as a stage for movably supporting the y-moving mechanisms 230, the movable levitation unit 17, and the like.

As shown in FIG. 1, for example, the conveyance unit 11 is configured so as to slide the end of the main levitation unit 10 in the +y direction along the conveyance direction. Further, the x-moving mechanism 220 and the y-moving mechanisms 230 are controlled independently of each other. The conveyance speed and the conveyance direction of the substrate 100 can be controlled by adjusting the moving speeds of the x-moving mechanism 220 and the y-moving mechanisms 230.

Each of the x-moving mechanism 220 and the y-moving mechanisms 230 may include, for example, an actuator such as a motor, a linear guide mechanism, an air bearing, and the like (not shown). The x-moving mechanism 220 and the y-moving mechanisms 230 are synchronized with each other, and move the holding mechanisms 12 in the x and y directions.

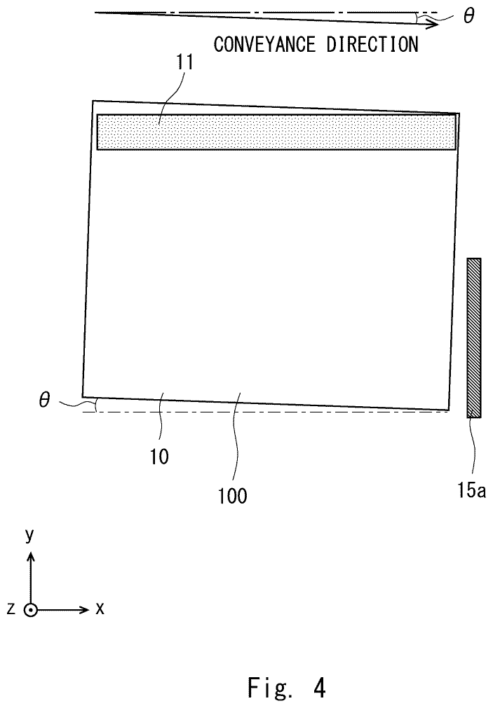

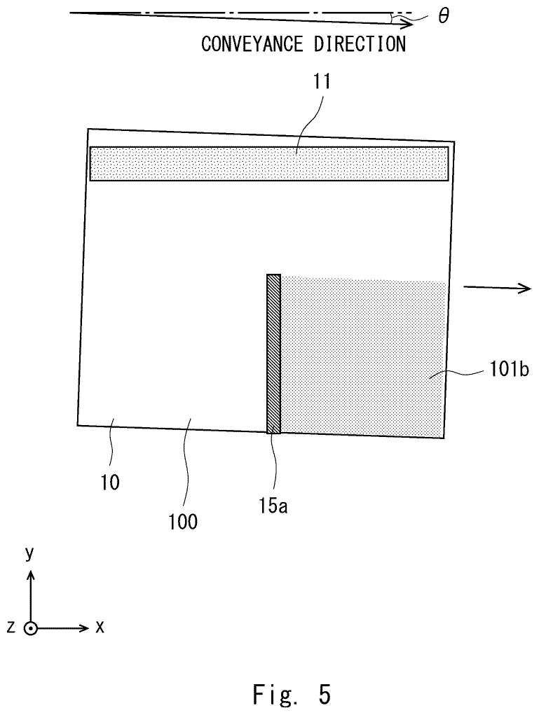

As shown in FIGS. 4 and 5, as the holding mechanisms 12 move along the conveyance direction, the substrate 100 is conveyed in the conveyance direction. The conveyance direction is inclined from the x direction. Further, in each of FIGS. 4 and 5, a straight line parallel to the x direction is indicated by a chain line. For example, when the angle between the x direction and the conveyance direction is represented by θ, the angle θ is larger than 0°. Then, by changing the moving speed in at least one of the x and y directions, the angle θ of the conveyance direction relative to the x direction can be changed. In this way, the substrate 100 can be conveyed at an angle suitable for the process. Further, when the y-moving mechanisms 230 are stopped, the angle θ can be set to 0° (θ=0°).

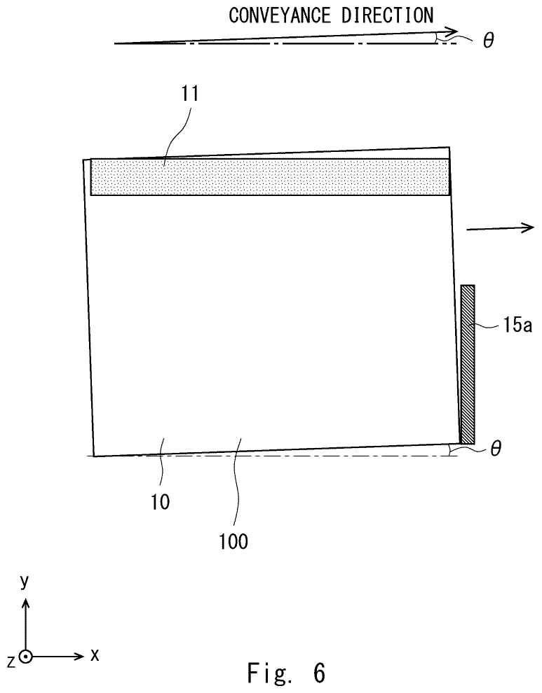

The angle θ of the conveyance direction can be adjusted by independently changing the moving speed in the x- or y direction. In this way, conveyance suitable for the process can be carried out. Further, as shown in FIG. 6, the moving direction of the y-moving mechanisms 230 can be made parallel to the y-axis positive direction. In this case, the sign, i.e., the plus/minus, of the angle θ of the conveyance direction can be changed. Specifically, when the angle θ in the configuration shown in FIG. 4 is defined as a positive value, the angle θ in the configuration shown in FIG. 6 becomes a negative value. That is, the angle θ becomes smaller than 0° in FIG. 6. The conveyance direction can be inclined so that the angle θ of the conveyance direction relative to the x direction becomes not only a positive value but also a negative value. For example, the angle θ can be varied in a range from −5° to +5°.

Further, as shown in FIG. 1, the main levitation unit 10 has a rectangular shape in the xy-plan view. Specifically, in the xy-plan view, the main levitation unit 10 has a rectangular shape having two sides parallel to the x direction and two sides parallel to the y direction. Further, the conveyance direction is inclined from the edge of the main levitation unit 10. In other words, the holding mechanisms 12 get closer to the main levitation unit 10 as they move in the +x direction. Further, the substrate 100 has a rectangular shape. Further, the substrate 100 is disposed so that its edge is inclined from the x and y directions. For example, the substrate 100 is disposed so that its edge is parallel to the conveyance direction. Alternatively, the substrate 100 may be disposed so that its edge is parallel to a direction inclined from the conveyance direction.

As shown in FIG. 4 and the like, the conveyance direction is parallel to the edge of the substrate 100. In this case, as shown in FIGS. 4 and 5, the angle formed by the edge of the substrate 100 and the x direction is also the angle θ. Further, the angle of the edge of the substrate 100 relative to the conveyance direction can be adjusted by rotating the substrate 100 around the z-axis. For example, the substrate 100 can be rotated in a range of −5° to 5°. In this way, even when the angle θ formed by the x direction and the conveyance direction is changed, the conveyance direction and the direction of the edge of the substrate 100 can be made parallel to each other. Needless to say, the conveyance direction and the direction of the edge of the substrate 100 may be different from each other.

As shown in FIG. 2, the substrate 100 is irradiated with laser light 15. Note that the irradiation area 15a of the laser light 15 in the substrate 100 has a line-like shape of which the longitudinal direction is parallel to the y direction. That is, in the irradiation area 15a, the y direction is the longitudinal direction (line direction), and the x direction is the lateral direction.

For example, the laser irradiation unit 14 includes an excimer laser light source or the like that generates laser light. Further, the laser irradiation unit 14 includes an optical system for guiding the laser light to the substrate 100. The laser irradiation unit 14 includes a lens(es) for concentrating the laser light 15 on the substrate 100. For example, the laser irradiation unit 14 includes a cylindrical lens for forming the linear irradiation area 15a. The substrate 100 is irradiated with line-shaped laser light, specifically, the laser light 15 (line beam) of which the focal point extends, i.e., stretches, in the y direction. The focal point of the laser light 15 is formed over the substrate 100. Therefore, in order to reduce in-plane variations, the levitation height needs to be accurate in the precision levitation area 31.

The substrate 100 is, for example, a glass substrate in which an amorphous film (amorphous silicon film 101a) is formed. The amorphous film can be crystallized by irradiating the amorphous film with laser light 15 and thereby performing an annealing process. For example, the amorphous silicon film 101a can be converted into a polycrystalline silicon film (polysilicon film 101b).

The laser irradiation apparatus 1 conveys the substrate 100 in the conveyance direction by holding the bottom surface of the substrate 100 using the conveyance unit 11 while levitating the substrate 100 using the levitation unit 10. Note that when the substrate 100 is conveyed, the conveyance unit 11 included in the laser irradiation apparatus 1 conveys the substrate 100 while the conveyance unit 11 is holding a part of the substrate 100 that does not overlap the irradiation area 15a in a plan view (i.e., as viewed in the z-direction). That is, as shown in FIG. 1, when the substrate 100 is conveyed in the conveyance direction, the part of the substrate 100 at which the main conveyance unit 11 holds the substrate 100 (which corresponds to the position of the holding mechanisms 12) does not overlap the irradiation area 15a.

For example, a planar shape of the substrate 100 is a quadrangle (a rectangular) having four sides and the main conveyance unit 11 (the holding mechanisms 12) holds only one of the four sides of the substrate 100. Further, the conveyance unit 11 (the holding mechanisms 12) holds a part of the substrate 100 that is not irradiated with laser light in a period during which the substrate 100 is being conveyed.

By the above-described configuration, it is possible to position the part of the substrate 100 at which the conveyance unit 11 holds the substrate 100 (which corresponds to the position of the holding mechanisms 12) and the irradiation area 15a away from each other. The irradiation area 15a is located roughly in a half of the substrate 100 in the −y direction, and the conveyance unit 11 holds the end the substrate 100 in the +y direction. It is possible to increase the distance between the place near the holding mechanisms 12 where the substrate 100 is bent widely and the irradiation area 15a. Therefore, it is possible to reduce the effect of the bending of the substrate 100 caused by the holding mechanisms 12 when laser light is applied to the substrate 100.

As shown in FIG. 4, the length of the irradiation area 15a in the y direction is roughly a half of the length of the substrate 100. As shown in FIG. 5, as the substrate 100 is conveyed, the laser light is applied to the area corresponding to the length of the irradiation area 15a. Then, in the area which has already been irradiated with the laser light, a polysilicon film 101b is formed.

When the substrate 100 passes the laser irradiation place 15a once, the amorphous silicon film 101a is crystallized in roughly a half of the area of the substrate 100. Then, after the substrate 100 is rotated about the z-axis by 180 degrees by a rotation mechanism (not shown), the conveyance unit 11 conveys the substrate 100 in the −x direction. Alternatively, after the rotated substrate 100 is conveyed in the −x direction, the conveyance unit 11 may convey the substrate 100 again in the +x direction. Then, when the substrate 100 is conveyed in the −x direction or when the substrate 100 is conveyed in the +x direction again after the rotation of 180 degrees, laser light is applied to the substrate 100. In this way, the substrate 100 passes through the laser irradiation place 15a, and the amorphous silicon film 101a is crystallized in the remaining half of the substrate 100. By making the substrate 100 perform a reciprocating movement as described above, the amorphous silicon film 101a is converted into a polycrystalline silicon film 101b over the substantially entire area of the substrate 100.

Further, the conveyance direction is inclined from the x direction, which is perpendicular to the linear irradiation area 15a. That is, the substrate 100 is conveyed in the conveyance direction inclined from the edge of the rectangular substrate 100. By inclining the conveyance direction from the x direction in the plan view, it is possible to perform conveyance of a substrate suitable for a laser irradiation process. Therefore, it is possible to appropriately perform a process for crystallizing a silicon film, and thereby to improve the display quality. By the above-described configuration, for example, it is possible to prevent an occurrence of a moire.

Assume that, for example, the substrate 100 is a glass substrate for an organic EL (Electro-Luminescence) display device. When the display area of the organic EL display device is rectangular, the edges of the display area are parallel to the edges of the substrate 100. That is, the organic EL display device has a rectangular display area of which the short sides are parallel to the x and y directions. When the conveyance direction is parallel to the x direction, laser light is applied to the substrate 100 in a state where the direction in which pixels are arranged is parallel to the irradiation area 15a.

As shown in this embodiment, it is possible to appropriately perform a laser irradiation process by inclining the conveyance direction from the x direction. The moving mechanism moves the holding mechanisms 12 in the conveyance direction inclined from the x direction perpendicular to the longitudinal direction of the linear irradiation area 15a in the plan view so as to change the irradiation place of the laser light over the substrate 100. In this way, it is possible to appropriately perform a process for crystallizing a silicon film. For example, it is possible to prevent an occurrence of a moire and thereby to improve the display quality.

Further, the conveyance unit 11 is capable of performing a two-axis operation. That is, the holding mechanisms 12 moves not only in the x direction but also in the y direction. In this case, it is necessary to widen the gap, i.e., clearance, between the main levitation unit 10 and the end levitation unit 18. That is, it is necessary to dispose the end levitation unit 18 away from the main levitation unit 10 in the Y direction. Even in such a case, the bending of the substrate 100 can be reduced by providing the movable levitation unit 17. Gas is ejected onto the bottom surface of the substrate 100 in the gap between the end levitation unit 18 and the main levitation unit 10. In this way, it is possible to prevent the substrate 100 from bending and thereby colliding with the main levitation unit 10 or any of the structures therearound.

Further, openings 171 are provided in the movable levitation unit 17. Further, the holding mechanisms 12 moves in the y direction inside the openings 171. Therefore, it is possible to adjust the conveyance direction of the substrate 100 with a simple configuration. Further, a plurality of openings 171 are provided in the movable levitation unit 17. Therefore, since a plurality of holding mechanisms 12 can hold the substrate 100, the substrate 100 can be reliably sucked and held.

According to this embodiment, a conveyance apparatus is configured to convey a substrate in order to irradiate the substrate with line-shaped laser light. The conveyance apparatus includes: a main levitation unit including an irradiation area disposed directly below an irradiation place of the laser light, and configured to levitate the substrate over a top surface thereof; a holding mechanism disposed outside the main levitation unit, and configured to hold the substrate over the main levitation unit; a first moving mechanism configured to move the holding mechanism in a first direction in order to change the irradiation place of the laser light over the substrate; and a second moving mechanism configured to move the holding mechanism and the first moving mechanism in a second direction inclined from the first direction in order to change the irradiation place of the laser light over the substrate.

According to another embodiment, a conveyance apparatus is configured to convey a substrate in order to irradiate the substrate with line-shaped laser light. The conveyance apparatus includes: a main levitation unit including an irradiation area disposed directly below an irradiation place of the laser light, and configured to levitate the substrate over a top surface thereof; a levitation unit disposed outside the main levitation unit, including an opening provided along a first direction, and configured to eject gas onto a bottom surface of the substrate; a holding mechanism disposed in the opening and configured to hold the substrate; and a first moving mechanism configured to move the holding mechanism and the levitation unit along the first direction.

According to this embodiment, a conveyance method is a conveyance method for conveying a substrate by using a conveyance apparatus in order to irradiate the substrate with line-shaped laser light, the conveyance apparatus including: a main levitation unit including an irradiation area disposed directly below an irradiation place of the laser light, and configured to levitate the substrate over a top surface thereof; and a holding mechanism disposed outside the main levitation unit, and configured to hold the substrate over the main levitation unit, the conveyance method including the steps of: (A1) moving, by a first moving mechanism, the holding mechanism in a first direction in order to change the irradiation place of the laser light over the substrate; and (A2) moving, by a second moving mechanism, the holding mechanism and the first moving mechanism in a second direction inclined from the first direction in order to change the irradiation place of the laser light over the substrate.

According to another embodiment, in a conveyance method, a conveyance apparatus is configured to convey a substrate in order to irradiate the substrate with line-shaped laser light, and includes: a main levitation unit including an irradiation area disposed directly below an irradiation place of the laser light, and configured to levitate the substrate over a top surface thereof; a movable levitation unit disposed outside the main levitation unit, including an opening provided along a first direction, and configured to eject gas onto a bottom surface of the substrate; and a holding mechanism disposed in the opening and configured to hold the substrate, and the conveyance method includes the step of (B1) moving, by a first moving mechanism, the holding mechanism and the movable levitation unit along the first direction.

According to this embodiment, a method for manufacturing a semiconductor device includes the steps of: (sa1) forming an amorphous film over a substrate; (sa2) loading the substrate with the amorphous film formed thereover on a conveyance apparatus; and (sa3) irradiating the substrate with line-shaped laser light while conveying the substrate using the conveyance apparatus, and thereby annealing the amorphous film so that the amorphous film is crystallized into a crystallized film, the conveyance apparatus including: a main levitation unit including an irradiation area disposed directly below an irradiation place of the laser light, and configured to levitate the substrate over a top surface thereof; a holding mechanism disposed outside the main levitation unit, and configured to hold the substrate over the main levitation unit; a first moving mechanism configured to move the holding mechanism in a first direction in order to change the irradiation place of the laser light over the substrate; and a second moving mechanism configured to move the holding mechanism and the first moving mechanism in a second direction inclined from the first direction in order to change the irradiation place of the laser light over the substrate.

According to another embodiment, a method for manufacturing a semiconductor device includes the steps of: (sb1) forming an amorphous film over a substrate; (sb2) loading the substrate with the amorphous film formed thereover on a conveyance apparatus; and (sb3) irradiating the substrate with line-shaped laser light while conveying the substrate using the conveyance apparatus, and thereby annealing the amorphous film so that the amorphous film is crystallized into a crystallized film, the conveyance apparatus including: a main levitation unit including an irradiation area disposed directly below an irradiation place of the laser light, and configured to levitate the substrate over a top surface thereof; a levitation unit disposed outside the main levitation unit, including an opening provided along a first direction, and configured to eject gas onto a bottom surface of the substrate; and a holding mechanism disposed in the opening and configured to hold the substrate, and a first moving mechanism configured to move the holding mechanism and the levitation unit along the first direction.

### Circulating Conveyance

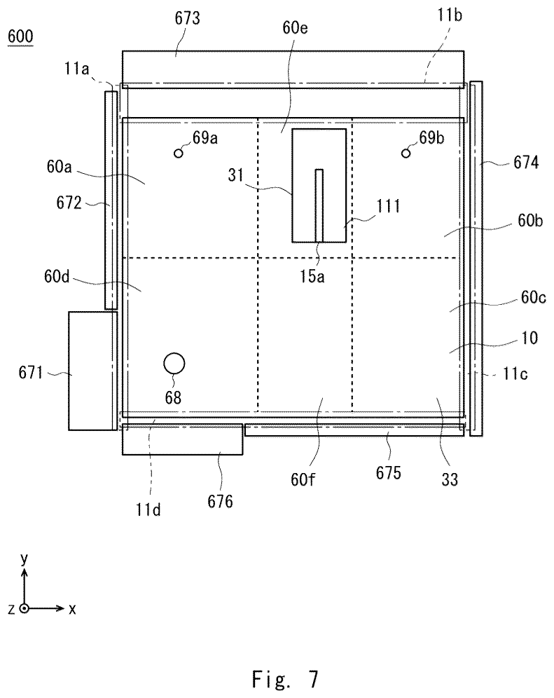

Next, an example of a configuration of a conveyance apparatus 600 will be described with reference to FIG. 7. FIG. 7 is a plan view showing the configuration of the conveyance apparatus 600. Note that descriptions of components, functions, and the like similar to those described above with reference to FIGS. 1 to 6 will be omitted as appropriate.

The conveyance apparatus 600 includes a main levitation unit 10 and end levitation units 671 to 676. The main levitation unit 10 levitates a substrate which is an object to be processed (not shown in FIG. 7). In the plan view, the main levitation unit 10 has a rectangular shape. The main levitation unit 10 includes two sides parallel to the y direction and two sides parallel to the x direction. Each of the end levitation units 671 to 676 levitates an end of the substrate protruding from the main levitation unit 10.

Here, for the sake of explanation, the main levitation unit 10 is divided into six areas 60a to 60f in the plan view. Specifically, the main levitation unit 10 includes first to fourth areas 60a to 60d, a process area 60e, and a passage area 60f. The first area 60a is a rectangular area including a corner on the −x side and the +y side (i.e., upper-left corner in FIG. 4). The second area 60b is a rectangular area including a corner on the +x side and the +y side (i.e., upper-right corner in FIG. 4). The third area 60c is a rectangular area including a corner on the +x side and the −y side (i.e., lower-right corner in FIG. 4). The fourth area 60d is a rectangular area including a corner on the −x side and the −y side (i.e., lower-left corner in FIG. 4).

The process area 60e is a rectangular area disposed between the first and second areas 60a and 60b. The process area 60e is an area including the irradiation area 15a to which laser light is applied. The passage area 60f is a rectangular area located between the third and fourth areas 60c and 60d.

The half of the area of the main levitation unit 10 on the +y side (i.e., the upper half area in FIG. 4) is composed of, in the order from the −x side (i.e., from the left side in FIG. 4), the first area 60a, the process area 60e, and the second area 60b. The half of the area of the main levitation unit 10 on the −y side (i.e., the lower half area in FIG. 4) is composed of, in the order from the +x side, the third area 60c, the passage area 60f, and the fourth area 60d.

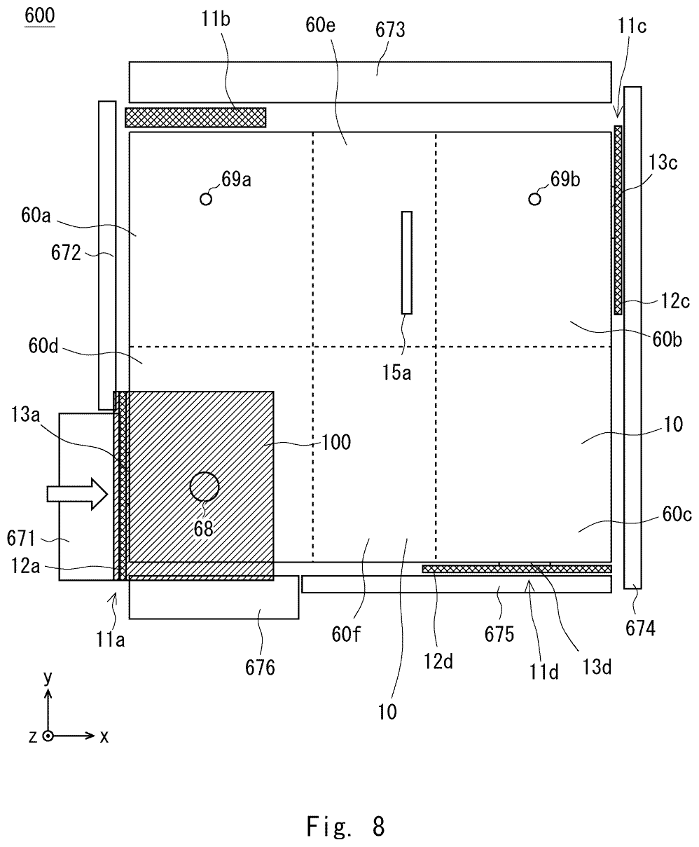

Further, the fourth area 60d serves as a carry-in area to which the substrate 100 (FIG. 8) is carried in and also a carry-out area from which the substrate 100 is carried out. For example, a loading machine such as a loading robot (not shown) is provided on the −x side of the fourth area 60d. Then, the loading machine carries in the substrate 100 to the fourth area 60d. Similarly, the loading machine carries out the substrate disposed in the fourth area 60d.

The main levitation unit 10 includes a rotation mechanism 68 and alignment mechanisms 69a and 69b. The rotation mechanism 68 rotates the substrate. Each of the alignment mechanisms 69a and 69b aligns the substrate. The alignment mechanisms 69a and 69b are provided in the first and second areas 60a and 60b, respectively. The rotation mechanism 68 is provided in the fourth area 60d. The operations of the rotation mechanism 68, the alignment mechanisms 69a and 69b, and the like will be described later.

The end levitation units 671 to 676 are disposed outside the main levitation unit 10. The end levitation units 671 to 676 are arranged along the outer periphery of the rectangular main levitation unit 10. The end levitation units 671 to 676 are arranged along the edges of the main levitation unit 10. In the plan view, the end levitation units 671 to 676 are arranged so as to surround the outer periphery of the main levitation unit 10.

The end levitation units 671 and 672 are disposed on the −x side of the main levitation unit 10. The end levitation unit 673 is disposed on the +y side of the main levitation unit 10. The end levitation unit 674 is disposed on the +x side of the main levitation unit 10. The end levitation units 675 and 676 are disposed on the −y side of the main levitation unit 10.

The end levitation units 671 and 672 are disposed along the edge of the main levitation unit 10 on the −x side. That is, each of the end levitation units 671 and 672 is disposed along the y direction. Further, the width of the end levitation unit 671 in the x direction is wider than that of the end levitation unit 672. The end levitation unit 671 is disposed on the −y side of the end levitation unit 672.

The end levitation unit 673 is disposed along the edge of the main levitation unit 10 on the +y side. That is, the end levitation unit 673 is disposed along the x direction. The end levitation unit 674 is disposed along the edge of the main levitation unit 10 on the +x side. That is, the end levitation unit 674 is disposed along the y direction.

The end levitation units 675 and 676 are arranged along the edge of the main levitation unit 10 on the −y side. That is, each of the end levitation units 675 and 676 is provided along the x direction. Further, the width of the end levitation unit 676 in the y direction is wider than that of the end levitation unit 675. The end levitation unit 676 is disposed on the −x side of the end levitation unit 675.

A conveyance unit 11a is provided between the main levitation unit 10 and the end levitation unit 671. A part of the conveyance unit 11a is also disposed between the main levitation unit 10 and the end levitation unit 672. The conveyance unit 11a is formed along the y direction. The conveyance unit 11a conveys the substrate in the +y direction. That is, the conveyance unit 11a conveys the substrate 100 from the fourth area 60d toward the first area 60a.

A conveyance unit 11b is provided between the main levitation unit 10 and the end levitation unit 673. The conveyance unit 11b is formed along the x direction. The conveyance unit 11b conveys the substrate in a conveyance direction inclined from the x direction. That is, the conveyance unit 11b conveys the substrate 100 from the first area 60a toward the second area 60b.

A conveyance unit 11c is provided between the main levitation unit 10 and the end levitation unit 674. The conveyance unit 11c is formed along the y direction. The conveyance unit 11c conveys the substrate 100 in the −y direction. That is, the conveyance unit 11c conveys the substrate 100 from the second area 60b toward the third area 60c.

A conveyance unit 11d is provided between the main levitation unit 10 and the end levitation unit 675. The conveyance unit 11d moves between the main levitation unit 10 and the end levitation unit 676. The conveyance unit 11d is formed along the x direction. The conveyance unit 11a conveys the substrate in the −x direction. That is, the conveyance unit 11d conveys the substrate 100 from the third area 60c toward the fourth area 60d.

Note that the conveyance unit 11b has a configuration similar to that of the conveyance unit 11 shown in FIGS. 1 and 3. Although the configuration of the conveyance unit 11b is shown in a simplified manner in FIGS. 7 and 8, it has a configuration similar to that shown in FIGS. 1 and 3 and the like. Therefore, the conveyance unit 11b includes the holding mechanisms 12, the x-moving mechanism 220, the y-moving mechanisms 230, and the like shown in FIG. 3 and the like. The conveyance unit 11b is capable of performing a two-axis operation and moves the substrate 100 in the x and y directions. Therefore, the conveyance direction of the substrate 100 is inclined from the x direction.

Each of the conveyance units 11a, 11c and 11d is different from the conveyance unit 11 shown in FIG. 1, and is capable of only a one-axis operation. Specifically, each of the conveyance units 11a and 11c holds the substrate 100 and conveys it only in the y direction. The conveyance unit 11d holds the substrate 100 and conveys it only in the x direction. Each of the conveyance units 11a, 11c and 11d has a holding mechanism for vacuum-sucking the substrate 100 and a moving mechanism for moving the holding mechanism.

Referring to FIG. 8, the conveyance unit 11a includes a holding mechanism 12a and a moving mechanism 13a. Similarly, the conveyance unit 11c includes a holding mechanism 12c and a moving mechanism 13c, and the conveyance unit 11d includes a holding mechanism 12d and a moving mechanism 13d. Each of the holding mechanisms 12a, 12c and 12d sucks and holds the substrate 100. The moving directions of the moving mechanisms 13a and 13c are parallel to the y direction. The moving direction of the moving mechanism 13d is parallel to the x direction. Further, each of the conveyance units 11a, 11c and 11d includes a lifting/lowering mechanism for moving the substrate 100 up and down (not shown).

As shown in FIG. 7, in the irradiation area 15a of the laser light, the y direction is the longitudinal direction. That is, a linear irradiation area 15a of which the longitudinal direction is parallel to the y direction is formed. The substrate 100 is irradiated with the laser light while the substrate 100 is being conveyed in the conveyance direction. A laser irradiation process is performed while the substate is moving from the first area 60a to the second area 60b. In this embodiment, the amorphous silicon film is also converted into a polysilicon film by irradiating the substrate with laser light from the laser light source.

Note that, in the main levitation unit 10, a precision levitation unit 111 is disposed in the irradiation area 15a and on the periphery thereof. The accuracy of the levitation height by the precision levitation unit 111 is higher than that of the rough levitation unit 113. Therefore, in the process area 60e, which includes the irradiation area 15a, the laser light is applied to the substrate 100 which is being levitated at a levitation height the accuracy of which is higher than that in the other areas 60a, 60b, 60c, 60d and 60f. In this way, it is possible to apply the laser light to the substrate 100 in a stable manner. Further, the areas other than the irradiation area 15a, such as the passage area 60f, the third area 60c, and the fourth area 60d, are manufactured without using an expensive precision levitation unit 111. Therefore, the cost of the apparatus can be reduced.

The conveyance unit 11b includes a movable levitation unit 17. Each of the conveyance units 11a, 11c and 11d includes no movable levitation unit 17. Therefore, the width of the conveyance unit 11b is wider than those of the conveyance units 11a, 11c and 11d. For example, the width of the conveyance unit 11b in the y direction is larger than that of the conveyance unit 11d in the y direction. Similarly, the width of the conveyance unit 11b in the y direction is larger than those of the conveyance units 11a, 11c in the x direction.

As described above, the width of the conveyance unit 11b is larger than those of the conveyance units 11a, 11c and 11d. Therefore, the gap, i.e., clearance, between the end levitation unit 673 and the main levitation unit 10 is wider than the gap between the main levitation unit 10 and any of the other end levitation units. For example, the gap between the end levitation unit 673 and the main levitation unit 10 in the y direction is wider than the gap between the end levitation unit 675 and the main levitation unit 10 in the y direction.

Next, a procedure according to a conveyance method using the main levitation unit 10 will be described with reference to FIGS. 8 to 15. In this example, the fourth area 60d is used as a place where the substrate 100 is carried in and carried out. Further, the substrate 100 carried into the fourth area 60d is conveyed from one area to another in the order of the first area 60a, the process area 60e, the second area 60b, the third area 60c, the passage area 60f, and the fourth area 60d. That is, the substrate 100 is moved in a circulating manner along the edges of the main levitation unit 10. In this example, the substrate 100 is moved in a circulating manner twice so that the entire area of the substrate 100 is irradiated with the laser light. That is, the substrate 100 is conveyed so that it is moved in a circulating manner twice over the main levitation unit 10. By doing so, substantially the entire surface of the substrate 100 is irradiated with the laser light.

The above-described procedure according to the conveyance method will be described hereinafter in detail. As shown in FIG. 8, the substrate 100 is carried into the fourth area 60d. The substrate 100 carried into the fourth area 60d is being levitated by the main levitation unit 10, and the end levitation units 671, 672 and 676. That is, the end of the substrate 100 on the −x side is being levitated by the end levitation units 671 and 672, and the central part thereof is being levitated by the main levitation unit 10. The end of the substrate 100 on the −y side is being levitated by the end levitation unit 676. Further, the holding mechanism 12a of the conveyance unit 11a holds the substrate 100.

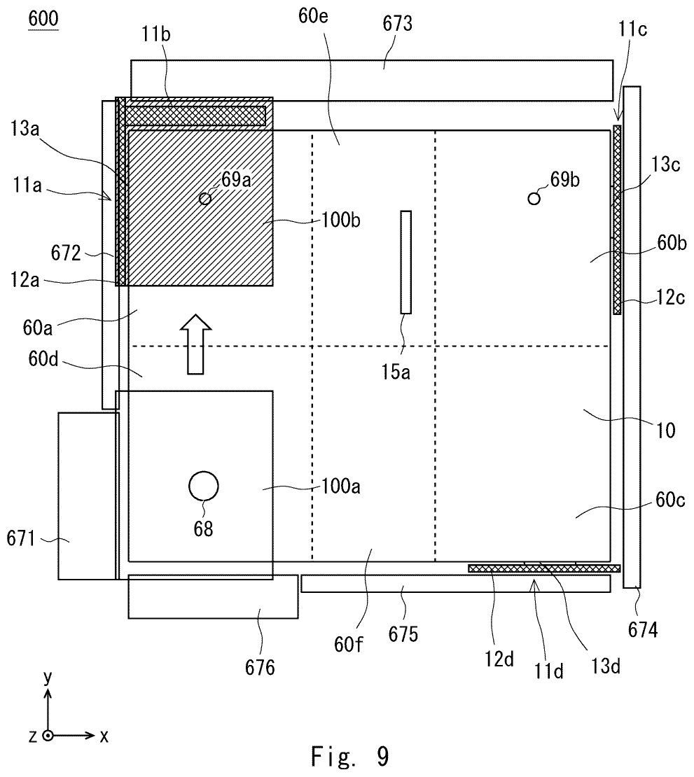

Next, as shown in FIG. 9, the substrate 100a in the fourth area 60d is conveyed to the first area 60a. The substrate that has been moved to the first area 60a is shown as a substrate 100b in FIG. 9. The holding mechanism 12a of the conveyance unit 11a is holding the substrate 100a. Then, the moving mechanism 13a moves the holding mechanism 12a in the +y direction, so that the substrate 100a is moved from the fourth area 60d to the first area 60a (indicted by an outlined arrow in FIG. 9).

In this process, in the xy-plan view, the holding mechanism 12a moves in the +y direction through the gap between the main levitation unit 10 and the end levitation unit 671. Further, in the xy-plan view, the holding mechanism 12a moves in the +y direction though the gap between the main levitation unit 10 and the end levitation unit 672. Therefore, the substrate 100b is being levitated by the main levitation unit 10, and the end levitation units 672 and 673. That is, the end of the substrate 100b on the −x side is being levitated by the end levitation unit 672, and the central part thereof is being levitated by the main levitation unit 10. The end of the substrate 100b on the +y side is being levitated by the end levitation unit 673.

Note that the conveyance unit 11b includes the movable levitation unit 17 as shown in FIGS. 1 to 3. When the substrate 100 is moved from the fourth area 60d to the first area 60a, the end of the substrate 100 on the +y side passes through the gap between the main levitation unit 10 and the end levitation unit 673. During this process, the movable levitation unit 17 ejects gas onto the substrate 100. In this way, it is possible to prevent the substrate 100 from bending and colliding with the edge of the main levitation unit 10 or the end levitation unit 673, or a structure therearound. As described above, the gap between the end levitation unit 673 and the main levitation unit 10 is wider than the gap between any of the other end levitation units and the main levitation unit 10. Even in such a case, it is possible to prevent the substrate 100 from bending by providing the movable levitation unit 17 in the conveyance unit 11b.

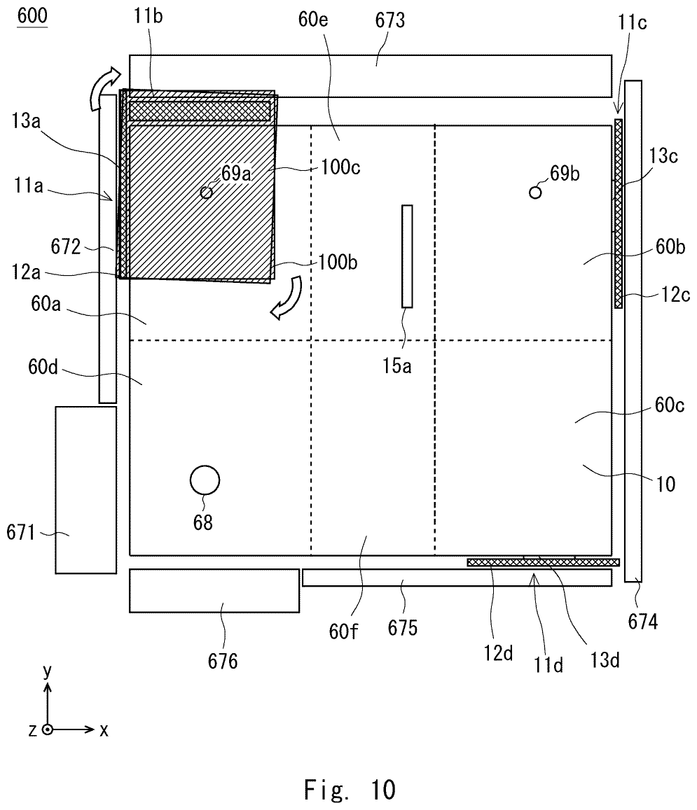

Next, as shown in FIG. 10, the alignment mechanism 69a aligns the position and the angle of the substrate 100b, which has been conveyed to the first area 60a. For example, the position and the rotation angle of the substrate 100 may be slightly deviated due to the carrying-in operation, the conveying operation, and/or the rotating operation of the substrate 100. The alignment mechanism 69a compensates for the deviation in the position and/or the rotation angle of the substrate. In this way, it is possible to accurately control the irradiation place of the laser light in the substrate 100.

For example, the alignment mechanism 69a can be moved in the y direction and can be rotated around the z-axis. Further, the alignment mechanism 69a can be moved in the z direction. For example, the alignment mechanism 69a includes an actuator such as a motor. The amounts of deviations in the position and the angle of the substrate 100b are obtained from an image thereof taken by a camera or the like. The alignment mechanism 69a performs alignment based on these deviation amounts.

The alignment mechanism 69a is disposed directly below the central part of the substrate 100b. The alignment mechanism 69a holds the substrate 100b. The alignment mechanism 69a may adsorb and hold the substrate 100b in a manner similar to that of the holding mechanism 12. The holding mechanism 12a releases (i.e., ceases) the holding of the substrate 100b. In this way, the substrate 100b is handed over from the holding mechanism 12a to the alignment mechanism 69a.

Then, the alignment mechanism 69a rotates the substrate 100b around the z-axis (indicted by an outlined arrow in FIG. 10). The alignment mechanism 69a rotates the substrate 100b so that the edge of the substrate 100b becomes parallel to the conveyance direction. The substrate after the rotation is shown as a substrate 100c. For example, the alignment mechanism 69a rotates the substrate 100 around the z-axis by a predetermined angle. The edge of the substrate 100c is parallel to the conveyance direction of the main levitation unit 10. Then, after the alignment is finished, the holding mechanism 12 of the conveyance unit 11b (FIGS. 1 and 3) holds the substrate 100b, and the alignment mechanism 69a releases the holding thereof. As a result, the substrate 100c is handed over from the alignment mechanism 69a to the holding mechanism 12 of the conveyance unit 11b.

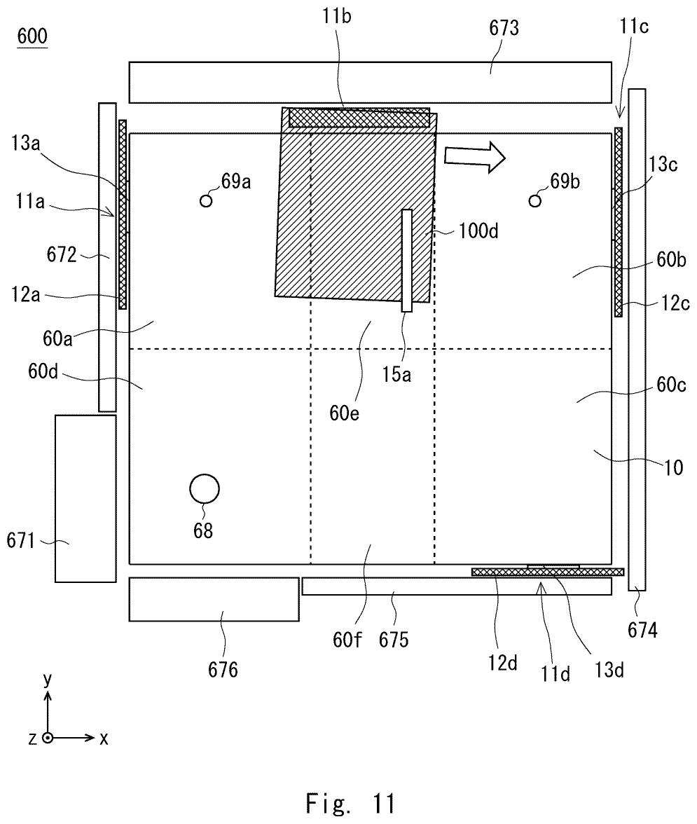

Next, as shown in FIG. 11, the conveying unit 11b moves the substrate 100d. As a result, the substrate 100d passes through the process area 60e. In this process, in the xy-plan view, the holding mechanism 12 moves in the direction inclined from the x direction through the gap between the main levitation unit 10 and the end levitation unit 673. In this way, substantially a half of the area of the substrate 100d passes through the irradiation area 15a. The laser light is applied to the substrate 100d, which is moving in the direction inclined from the x direction perpendicular to the irradiation area 15a.

In the xy-plan view, the holding mechanisms 12 move through the gap between the main levitation unit 10 and the end levitation unit 673. Therefore, the substrate 100d is being levitated by the main levitation unit 10 and the end levitation unit 673. That is, the end of the substrate 100d on the +y side is being levitated by the end levitation unit 673, and the central part thereof is being levitated by the main levitation unit 10. A laser irradiation process is performed while the substate is moving from the first area 60a to the second area 60b.

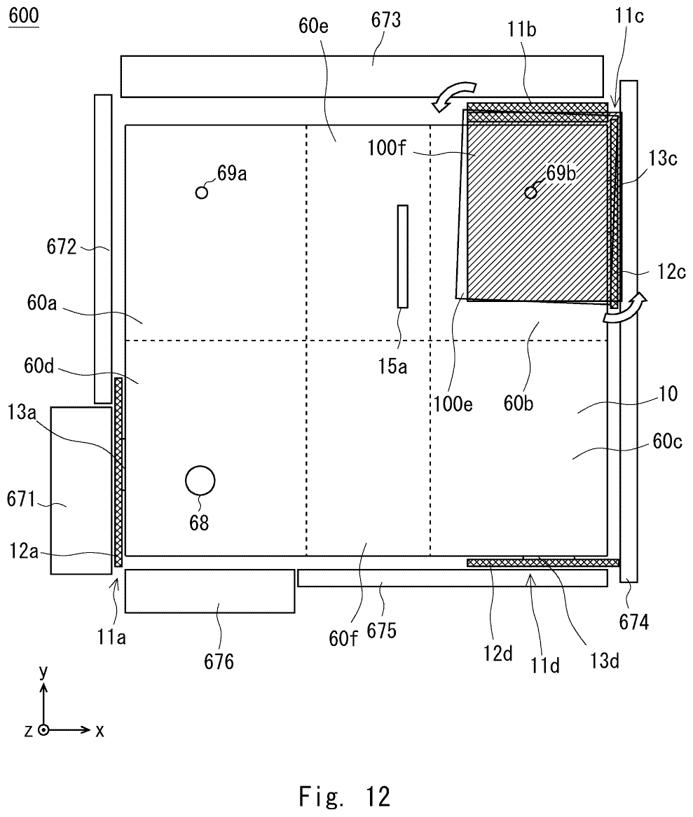

Next, as shown in FIG. 12, when the substrate 100e has moved to the second area 60b, the alignment mechanism 69b aligns the substrate 100e. In this process, the alignment mechanism 69b rotates the substrate 100e (indicted by an outlined arrow in FIG. 12). The substrate after the rotation is shown as a substrate 100f in FIG. 12.

The alignment mechanism 69b is disposed directly below the central part of the substrate 100e. The alignment mechanism 69b holds the substrate 100e. The alignment mechanism 69b may adsorb and hold the substrate 100e in a manner similar to that of the holding mechanism 12. Further, the holding mechanism 12 releases the holding of the substrate 100e. The substrate 100e is handed over from the holding mechanism 12 of the conveyance unit 11b to the alignment mechanism 69b.

The alignment mechanism 69b rotates the substrate 100e around the z-axis (indicted by an outlined arrow in FIG. 12). The alignment mechanism 69a rotates the substrate 100e so that the edge of the substrate 100e becomes parallel to the y direction of the main levitation unit 10. After the rotation, the edges of the substrate 100f are parallel to the x or y direction. Then, after the alignment is finished, the holding mechanism 12c of the conveyance unit 11c holds the substrate 100f, and the alignment mechanism 69b releases the holding thereof. As a result, the substrate 100f is handed over from the alignment mechanism 69b to the holding mechanism 12c of the conveyance unit 11c.

The substrate 100e is being levitated by the main levitation unit 10, and the end levitation units 673 and 674. That is, the end of the substrate 100e on the +y side is being levitated by the end levitation unit 673. The end of the substrate 100e on the +x side is being levitated by the end levitation unit 674, and the central part thereof is being levitated by the main levitation unit 10.

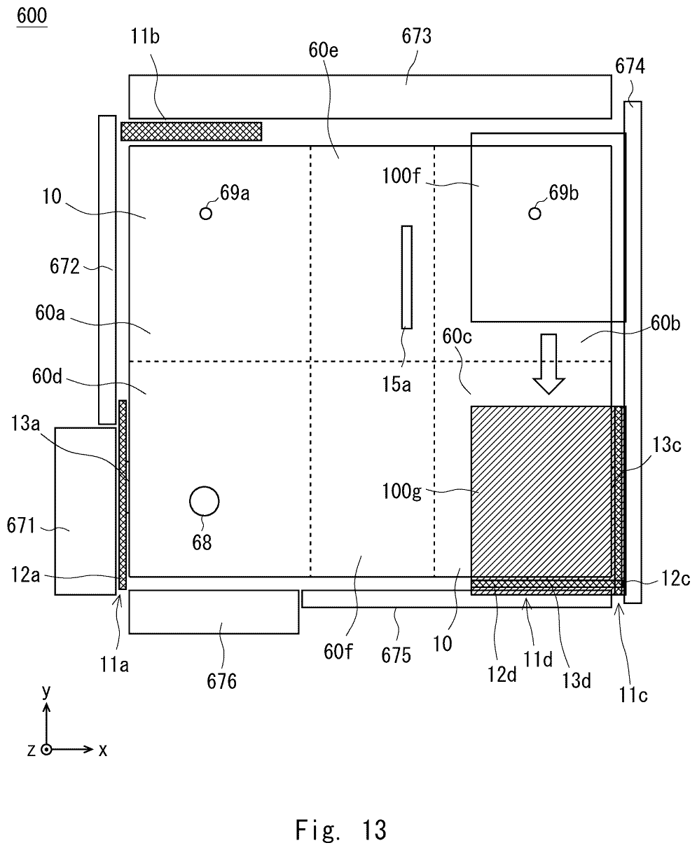

Next, as shown in FIG. 13, the substrate 100f, which is located in the second area 60b, is conveyed to the third area 60c. The substrate that has moved to the third area 60c is shown as a substrate 100g. In FIG. 13, the holding mechanism 12c of the conveyance unit 11c is holding the substrate 100f. Then, the moving mechanism 13c moves the holding mechanism 12c in the −y direction, so that the substrate 100f is moved from the second area 60b to the third area 60c (indicted by an outlined arrow in FIG. 13).

In this process, in the xy-plan view, the holding mechanism 12c moves in the −y direction through the gap between the main levitation unit 10 and the end levitation unit 674. Therefore, the substrate 100e is being levitated by the main levitation unit 10, and the end levitation units 674 and 675. The end of the substrate 100e on the +x side is being levitated by the end levitation unit 674, and the central part thereof is being levitated by the main levitation unit 10. The end of the substrate 100e on the −y side is being levitated by the end levitation unit 675.

Then, the holding mechanism 12d of the conveyance unit 11d holds the substrate 100g, and the holding mechanism 12c releases the holding thereof. As a result, the substrate 100g is handed over from the holding mechanism 12c of the conveyance unit 11c to the holding mechanism 12d of the conveyance unit 11d.

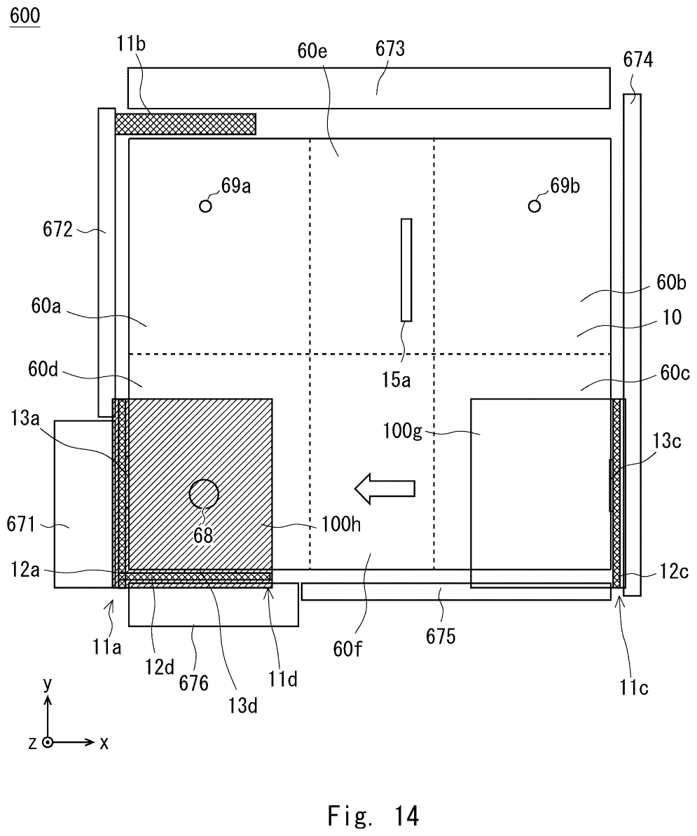

Next, as shown in FIG. 14, the substrate 100g, which is located in the third area 60c, is conveyed to the fourth area 60d. The substrate that has moved to the fourth area 60d is shown as a substrate 100h. In FIG. 14, the holding mechanism 12d of the conveyance unit 11d is holding the substrate 100g. Then, the moving mechanism 13d moves the holding mechanism 12d in the −x direction, so that the substrate 100f is moved from the third area 60c to the fourth area 60d (indicted by an outlined arrow in FIG. 14).

In this process, in the xy-plan view, the holding mechanism 12d moves in the −x direction through gap between the main levitation unit and the end levitation unit 675. In the xy-plan view, the holding mechanism 12d moves in the −x direction through the gap between the main levitation unit 10 and the end levitation unit 676. Therefore, the substrate 100h is being levitated by the main levitation unit 10 and the end levitation unit 676. The end of the substrate 100h on the −y side is being levitated by the end levitation unit 676, and the central part thereof is being levitated by the main levitation unit 10. The end of the substrate 100h on the −x side is being levitated by the end levitation unit 671.

In this way, the substrate 100, which was originally disposed in the fourth area 60d, is moved from one area to another in the order of the first area 60a, the process area 60e, the second area 60b, the third area 60c, the passage area 60f, and the fourth area 60d. That is, the substrate 100 is moved in a circulating manner along the edges of the main levitation unit 10.

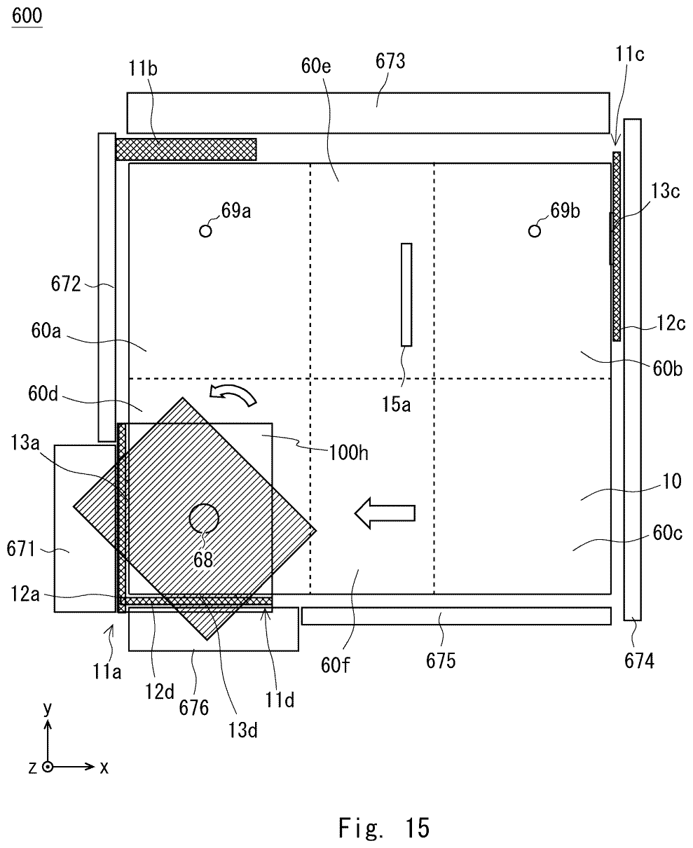

Next, as shown in FIG. 15, the rotation mechanism 68 rotates the substrate 100h around the z-axis by 180°. That is, the substrate 100h is handed over from the holding mechanism 12d to the rotation mechanism 68. After the rotation mechanism 68 rotates the substrate 100h, the substrate 100h is handed over from the rotation mechanism 68 to the holding mechanism 12d.

Similarly to the above-described processes, the conveyance units 11a to 11d move the substrate 100h again from one area to another in the order of the first area 60a, the process area 60e, the second area 60b, the third area 60c, the passage area 60f, and the fourth area 60d. That is, as shown in FIGS. 7 to 15, the substrate 100 is moved in a circulating manner along the edges of the main levitation unit 10.

In this example, the rotation mechanism 68 rotates the substrate 100h by 180°. When the substrate 100e passes through the process area 60e for the second time, the laser light is applied to the remaining half of the area of the substrate that was not irradiated with the laser light in the first passage. As described above, the substrate 100 is moved in a circulating manner twice along the edges of the main levitation unit 10. Since the substrate 100 is rotated 180° between the first laser irradiation and the second laser irradiation, substantially the entire surface of the substrate 100 is irradiated with the laser light. Note that the place in which the substrate 100 is rotated is not limited to the first area 60a. For example, the rotation may be performed in the second area 60b, the third area 60c, the fourth area 60d, or the like.

The conveyance unit 11b conveys the substrate 100 in a conveyance direction inclined from the x direction perpendicular to the irradiation area 15a. In this way, it is possible to appropriately perform a process for crystallizing a silicon film. For example, it is possible to prevent an occurrence of a moire and thereby to improve the display quality. Needless to say, the conveyance direction of the substrate 100 may be parallel to the x direction. It is sufficient if the conveyance direction of the substrate 100 is a direction inclined from the y direction in the plan view. That is, the conveyance direction of the substrate may be parallel to the x direction or a direction inclined from the x direction.

Note that the above descriptions are given on the assumption that the conveyance units 11a, 11c and 11d convey the substrate 100 in a state in which the edges of the substrate 100 are parallel to the x and y directions. However, the substrate 100 may be conveyed in a state in which the edges of the substrate 100 are inclined from the x and y directions. That is, the conveyance units 11a, 11c and 11d may convey the substrate 100 in a state in which the substrate 100 is parallel to the conveyance direction. In this case, the adjustment of the rotation angle by the alignment mechanisms 69a and 69b in FIGS. 10 and 12 becomes unnecessary. Therefore, the alignment mechanisms 69a and 69b may not be provided.

Further, when the conveyance unit 11b conveys the substrate 100, the holding mechanism holds the short side of the substrate 100 in FIG. 11, but it may hold the long side of the substrate 100. In this case, after the rotation mechanism 68 rotates the substrate 100 by 90° in FIG. 8, the conveyance unit 11a may convey the substrate 100. Alternatively, the loading machine may convey the substrate 100 to the fourth area 60d in a state in which the long side of the substrate 100 is parallel to the x direction or the conveyance direction.

### Organic EL Display

A semiconductor device having the above-described polysilicon film is suitable for a TFT (Thin Film transistor) array substrate for an organic EL (Electro Luminescence) display. That is, the polysilicon film is used as a semiconductor layer including source regions, channel regions, and drain regions of TFTs.

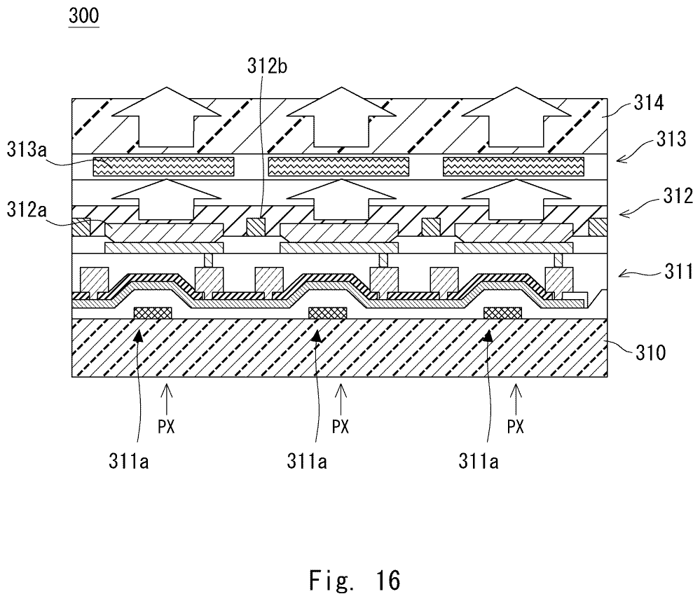

A configuration in which a semiconductor device according to this embodiment is applied to an organic EL display will be described hereinafter. FIG. 16 is a simplified cross-sectional view of pixel circuits of an organic EL display device. The organic EL display 300 shown in FIG. 16 is an active matrix-type display device in which a TFT(s) is disposed in each pixel PX.

The organic EL display device 300 includes a substrate 310, a TFT layer 311, an organic layer 312, a color filter layer 313, and a sealing substrate 314. FIG. 16 shows a top-emission-type organic EL display device, in which the side of the sealing substrate 314 is located on the viewing side. Note that the following description is given to show an example of a configuration of an organic EL display device and this embodiment is not limited to the below-described configuration. For example, a semiconductor device according to this embodiment may be used for a bottom-emission-type organic EL display device.

The substrate 310 is a glass substrate or a metal substrate. The TFT layer 311 is provided over the substrate 310. The TFT layer 311 includes TFTs 311a disposed in the respective pixels PX. Further, the TFT layer 311 includes wiring lines (not shown) or the like connected to the TFTs 311a. The TFTs 311a, the wirings, and the like constitute pixel circuits.

The organic layer 312 is provided over the TFT layer 311. The organic layer 312 includes an organic EL light-emitting element 312a disposed in each pixel PX. Further, in the organic layer 312, separation walls 312b for separating organic EL light-emitting elements 312a are provided between pixels PX.

The color filter layer 313 is provided over the organic layer 312. The color filter layer 313 includes color filters 313a for performing color displaying. That is, in each pixel PX, a resin layer colored in R (red), G (green), or B (blue) is provided as the color filter 313a.

The sealing substrate 314 is provided over the color filter layer 313. The sealing substrate 314 is a transparent substrate such as a glass substrate and is provided to prevent deterioration of the organic EL light-emitting elements of the organic layer 312.

Electric currents flowing through the organic EL light-emitting elements 312a of the organic layer 312 are changed by display signals supplied to the pixel circuits. Therefore, it is possible to control an amount of light emitted in each pixel PX by supplying a display signal corresponding to a display image to each pixel PX. As a result, it is possible to display a desired image.

In an active matrix-type display device such as an organic EL display, at least one TFT (e.g., a switching TFT or a driving TFT) is provided in one pixel PX. Further, a semiconductor layer including a source region, a channel region, and a drain region is provided in the TFT in each pixel PX. A polysilicon film according to this embodiment is suitable for a semiconductor layer of TFTs. That is, by using a polysilicon film manufactured by the above-described manufacturing method for a semiconductor layer of a TFT array substrate, it is possible to prevent or reduce in-plane variations of TFT characteristics. Therefore, it is possible to manufacture display devices having excellent display characteristics with high productivity.

### Method for Manufacturing Semiconductor Device

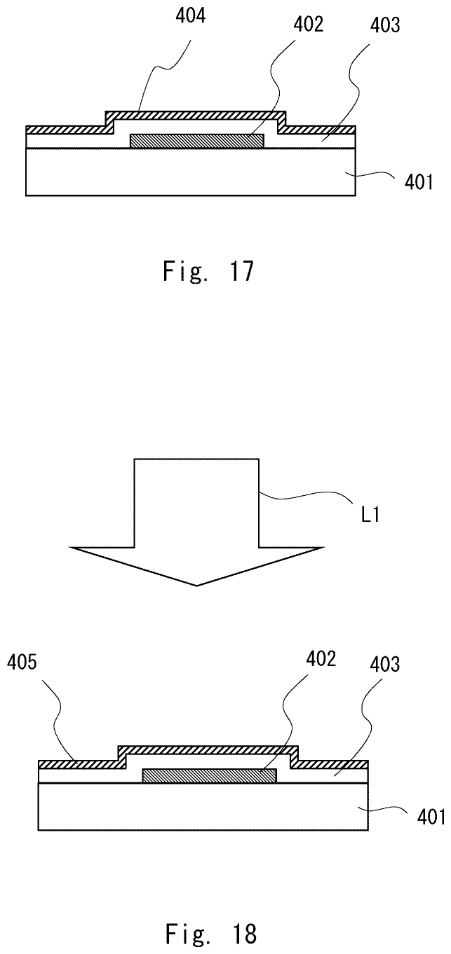

The method for manufacturing a semiconductor device by using a laser irradiation apparatus according to this embodiment is suitable for manufacturing of a TFT array substrate. A method for manufacturing a semiconductor device including a TFT will be described with reference to FIGS. 17 and 18. Each of FIGS. 17 and 18 is a cross-sectional view showing a step in a method for manufacturing a semiconductor device. In the following description, a method for manufacturing a semiconductor device including an inverted staggered-type TFT will be described. Each of FIGS. 17 and 18 shows one of the steps for forming a polysilicon film in a method for manufacturing a semiconductor. Note that other manufacturing steps can be performed by using known techniques, and therefore descriptions thereof are omitted as appropriate.

As shown in FIG. 17, a gate electrode 402 is formed over a glass substrate 401. A gate insulating film 403 is formed over the gate electrode 402. An amorphous silicon film 404 is formed over the gate insulating film 403. The amorphous silicon film 404 is disposed so as to be placed over the gate electrode 402 with the gate insulating film 403 interposed therebetween. For example, the gate insulating film 403 and the amorphous silicon film 404 are successively formed by a CVD (Chemical Vapor Deposition) method.

Then, the glass substrate 401, on which the amorphous silicon film 404 has been formed, is conveyed to the above-described conveyance apparatus 600. Then, by irradiating the amorphous silicon film 404 with laser light L1, a polysilicon film 405 is formed as shown in FIG. 18. That is, the amorphous silicon film 404 is crystallized by the laser irradiation apparatus 1 shown in FIG. 1 or the like. As a result, a polysilicon film 405 that is formed as silicon is crystallized is formed over the gate insulating film 403. The polysilicon film 405 corresponds to the above-described polysilicon film. The glass substrate 401 is irradiated with the laser light LI while the conveyance apparatus 600 is conveying the glass substrate 401. As a result, the amorphous silicon film 404 is annealed and converted into a polysilicon film 405.

Further, the above descriptions are given on the assumption that a laser annealing apparatus according to this embodiment is one in which a polysilicon film is formed by applying laser light to an amorphous silicon film. However, the present disclosure may be applied to other cases in which a micro-crystalline film is formed by applying laser light to an amorphous silicon film. Further, the laser light used for the annealing is not limited to Nd:YAG laser. Further, a method according to this embodiment can also be applied to a laser annealing apparatus for crystallizing a thin film other than the silicon film. That is, the method according to this embodiment can be applied to any laser annealing apparatus in which a crystallized film is formed by applying laser light to an amorphous film. According to the laser annealing apparatus in accordance with this embodiment, it is possible to appropriately reform (or modify) a substrate including a crystallized film.

Note that the present invention is not limited to the above-described embodiments, and they can be modified as appropriate without departing from the scope and spirit of the invention.

### REFERENCE SIGNS LIST

1 LASER IRRADIATION APPARATUS
10 MAIN FLOATATION UNIT
11 CONVEYANCE UNIT
12 HOLDING MECHANISM
14 LASER IRRADIATION UNIT
15 LASER BEAM
15a IRRADIATED AREA
17 MOVABLE FLOATATION UNIT
18 END FLOATATION UNIT
31 PRECISION FLOATATION AREA
33 ROUGH FLOATATION AREA
60a FIRST AREA
60b SECOND AREA
60c THIRD AREA
60d FOURTH AREA
60e PROCESS AREA
60f PASSAGE AREA
671-676 END FLOATATION UNIT
68 ROTATION MECHANISM
69a, 69b ALIGNMENT MECHANISM
100 SUBSTRATE
111 PRECISION FLOATATION UNIT
113 ROUGH FLOATATION UNIT
131 FLOATATION UNIT CELL
220 X-MOVING MECHANISM
230 Y-MOVING MECHANISM
240 LIFTING/LOWERING MECHANISM
300 ORGANIC EL DISPLAY
310 SUBSTRATE
311 TFT LAYER
311a TFT
312 ORGANIC LAYER
312a ORGANIC EL LIGHT-EMITTING ELEMENT
312b SEPARATION WALL
313 COLOR FILTER LAYER
313a COLOR FILTER (CF)
314 SEALING SUBSTRATE
401 GLASS SUBSTRATE
402 GATE ELECTRODE
403 GATE INSULATING FILM
404 AMORPHOUS SILICON FILM
405 POLYSILICON FILM
671-676 END FLOATING UNIT
PX PIXEL

1. A conveyance apparatus configured to convey a substrate in order to irradiate the substrate with line-shaped laser light, comprising:
a main levitation unit comprising an irradiation area disposed directly below an irradiation place of the laser light, and configured to levitate the substrate over a top surface thereof;
a holding mechanism disposed outside the main levitation unit, and configured to hold the substrate over the main levitation unit;
a first moving mechanism configured to move the holding mechanism in a first direction in order to change the irradiation place of the laser light over the substrate; and
a second moving mechanism configured to move the holding mechanism and the first moving mechanism in a second direction inclined from the first direction in order to change the irradiation place of the laser light over the substrate.

2. The conveyance apparatus according to claim 1, further comprising a movable levitation unit with an opening formed along a first direction, configured to eject gas onto a bottom surface of the substrate, wherein
the second moving mechanism moves the movable levitation unit in a second direction, and
the first moving mechanism moves the holding mechanism so that the holding mechanism moves in the first direction inside the opening.

3. A conveyance apparatus configured to convey a substrate in order to irradiate the substrate with line-shaped laser light, comprising:
a main levitation unit comprising an irradiation area disposed directly below an irradiation place of the laser light, and configured to levitate the substrate over a top surface thereof;
a levitation unit disposed outside the main levitation unit, comprising an opening provided along a first direction, and configured to eject gas onto a bottom surface of the substrate;
a holding mechanism disposed in the opening and configured to hold the substrate; and
a first moving mechanism configured to move the holding mechanism and the levitation unit along the first direction.

4. The conveyance apparatus according to claim 3, further comprising a second moving mechanism configured to move the holding mechanism and the levitation unit along a second direction inclined from the first direction in a plan view, wherein
the first moving mechanism moves the holding mechanism in the first direction while the second moving mechanism is moving the holding mechanism and the levitation unit in the second direction, so that the irradiation place of the laser light over the substrate is changed.

5. The conveyance apparatus according to claim 1, further comprising a lifting/lowering mechanism configured to lift and lower the holding mechanism, wherein
the first moving mechanism moves the lifting/lowering mechanism in the first direction.

6. The conveyance apparatus according to claim 1, further comprising an end levitation unit configured to eject gas onto a bottom surface of an end of the substrate, wherein
the holding mechanism moves between the end levitation unit and the main levitation unit.

7. A conveyance method for conveying a substrate by using a conveyance apparatus in order to irradiate the substrate with line-shaped laser light,
the conveyance apparatus comprising:
a main levitation unit comprising an irradiation area disposed directly below an irradiation place of the laser light, and configured to levitate the substrate over a top surface thereof; and
a holding mechanism disposed outside the main levitation unit, and configured to hold the substrate over the main levitation unit,
the conveyance method comprising the steps of:
(A1) moving, by a first moving mechanism, the holding mechanism in a first direction in order to change the irradiation place of the laser light over the substrate; and
(A2) moving, by a second moving mechanism, the holding mechanism and the first moving mechanism in a second direction inclined from the first direction in order to change the irradiation place of the laser light over the substrate.

8. The conveyance method according to claim 7, wherein
the conveyance apparatus further comprises a movable levitation unit with an opening formed along the first direction, configured to eject gas onto a bottom surface of the substrate,
the second moving mechanism moves the movable levitation unit in a second direction, and
the first moving mechanism moves the holding mechanism so that the holding mechanism moves in the first direction inside the opening.

9. A conveyance apparatus configured to convey a substrate in order to irradiate the substrate with line-shaped laser light, comprising:
a main levitation unit comprising an irradiation area disposed directly below an irradiation place of the laser light, and configured to levitate the substrate over a top surface thereof;
a movable levitation unit disposed outside the main levitation unit, comprising an opening provided along a first direction, and configured to eject gas onto a bottom surface of the substrate; and
a holding mechanism disposed in the opening and configured to hold the substrate, and
the conveyance method comprises the step of (B1) moving, by a first moving mechanism, the holding mechanism and the movable levitation unit along the first direction.

10. The conveyance method according to claim 9, wherein
the conveyance apparatus further comprises a second moving mechanism configured to move the holding mechanism and the movable levitation unit along a second direction inclined from the first direction in a plan view, and
the first moving mechanism moves the holding mechanism in the first direction while the second moving mechanism is moving the holding mechanism and the movable levitation unit in the second direction, so that the irradiation place of the laser light over the substrate is changed.

11. The conveyance method according to claim 7, wherein
the conveyance apparatus further comprises a lifting/lowering mechanism configured to lift and lower the holding mechanism, and
the first moving mechanism moves the lifting/lowering mechanism in the first direction.

12. The conveyance method according to claim 7, wherein
the conveyance apparatus further comprises an end levitation unit configured to eject gas onto a bottom surface of an end of the substrate, and
the holding mechanism moves between the end levitation unit and the main levitation unit.

13. A method for manufacturing a semiconductor device, comprising the steps of:
(sa1) forming an amorphous film over a substrate;
(sa2) loading the substrate with the amorphous film formed thereover onto a conveyance apparatus; and
(sa3) irradiating the substrate with line-shaped laser light while conveying the substrate using the conveyance apparatus, and thereby annealing the amorphous film so that the amorphous film is crystallized into a crystallized film,
the conveyance apparatus comprising:
a main levitation unit comprising an irradiation area disposed directly below an irradiation place of the laser light, and configured to levitate the substrate over a top surface thereof;
a holding mechanism disposed outside the main levitation unit, and configured to hold the substrate over the main levitation unit;
a first moving mechanism configured to move the holding mechanism in a first direction in order to change the irradiation place of the laser light over the substrate; and
a second moving mechanism configured to move the holding mechanism and the first moving mechanism in a second direction inclined from the first direction in order to change the irradiation place of the laser light over the substrate.

14. The method for manufacturing a semiconductor device according to claim 13, wherein
the conveyance apparatus further comprises a movable levitation unit with an opening formed along the first direction, configured to eject gas onto a bottom surface of the substrate,
the second moving mechanism moves the movable levitation unit in a second direction, and
the first moving mechanism moves the holding mechanism so that the holding mechanism moves in the first direction inside the opening.

15. A method for manufacturing a semiconductor device, comprising the steps of:
(sb1) forming an amorphous film over a substrate;
(sb2) loading the substrate with the amorphous film formed thereover onto a conveyance apparatus; and
(sb3) irradiating the substrate with line-shaped laser light while conveying the substrate using the conveyance apparatus, and thereby annealing the amorphous film so that the amorphous film is crystallized into a crystallized film, wherein
the conveyance apparatus comprises:
a main levitation unit comprising an irradiation area disposed directly below an irradiation place of the laser light, and configured to levitate the substrate over a top surface thereof;
a levitation unit disposed outside the main levitation unit, comprising an opening provided along a first direction, and configured to eject gas onto a bottom surface of the substrate;
a holding mechanism disposed in the opening and configured to hold the substrate; and
a first moving mechanism configured to move the holding mechanism and the levitation unit along the first direction.

16. The method for manufacturing a semiconductor device according to claim 15, wherein
the conveyance apparatus further comprises a second moving mechanism configured to move the holding mechanism and the levitation unit along a second direction inclined from the first direction in a plan view, and
the first moving mechanism moves the holding mechanism in the first direction while the second moving mechanism is moving the holding mechanism and the levitation unit in the second direction, so that the irradiation place of the laser light over the substrate is changed.

17. The method for manufacturing a semiconductor device according to claim 13, wherein
the conveyance apparatus further comprises a lifting/lowering mechanism configured to lift and lower the holding mechanism, and
the first moving mechanism moves the lifting/lowering mechanism in the first direction.

18. The method for manufacturing a semiconductor device according to claim 13, wherein
the conveyance apparatus further comprises an end levitation unit configured to eject gas onto a bottom surface of an end of the substrate, and
the holding mechanism moves between the end levitation unit and the main levitation unit.

19. The conveyance apparatus according to claim 1, wherein the holding mechanism holds the substrate at an edge part of the substrate outside of the irradiation place, and
a moving speed of the first moving mechanism and a moving speed of the second moving mechanism are adjusted so that the substrate moves linearly along a direction inclined from the line-shaped laser light in a plan view.

20. The conveyance apparatus according to claim 3, wherein the holding mechanism holds the substrate at an edge part of the substrate outside of the irradiation place, and
a moving speed of the first moving mechanism and a moving speed of the second moving mechanism are adjusted so that the substrate moves linearly along a direction inclined from the line-shaped laser light in a plan view.
